(19) United States
(12) Patent Application Publication
(10) Pub. No.: US 2025/0015108 A1
(43) Pub. Date: Jan. 9, 2025

(54) IMAGE SENSOR

(71) Applicant: Samsung Electronics Co., Ltd., Suwon-si (KR)

(72) Inventors: Younggu JIN, Suwon-si (KR); Youngchan KIM, Suwon-si (KR); Seunghyun LEE, Suwon-si (KR); Taeun HWANG, Suwon-si (KR)

(73) Assignee: Samsung Electronics Co., Ltd., Suwon-si (KR)

(21) Appl. No.: 18/625,295

(22) Filed: Apr. 3, 2024

(30) Foreign Application Priority Data
Jul. 5, 2023 (KR) 10-2023-0087268

(51) Int. Cl. H01L 27/146

(52) U.S. Cl. CPC H01L 27/14627; H01L 27/14603; H01L 27/14623

(57) ABSTRACT

An image sensor that includes a substrate including a first photodiode (PD) region and a second PD region adjacent to the first PD region; a first PD having a first area in the first PD region; a second PD in the second PD region, the second PD having a second area smaller than the first area; a micro-lens on the substrate and covering the first PD region; and a light splitter between the substrate and the micro-lens, the light splitter including a material having a refractive index different from a refractive index of the micro-lens. The light splitter extends from the first PD region to the second PD region.

### CROSS-REFERENCE TO RELATED APPLICATION

This application is based on and claims priority under 35 USC § 119 to Korean Patent Application No. 10-2023-0087268, filed on Jul. 5, 2023, in the Korean Intellectual Property Office, the disclosure of which is incorporated by reference herein in its entirety.

### BACKGROUND

The present disclosure relates to image sensors, and more particularly, to image sensors having a split photodiode (PD) structure.

Image sensors, as semiconductor-based sensors, generate electrical signals upon receiving light and may include a pixel array having a plurality of pixels and a circuit for driving the pixel array and generating an image. The pixels may each include a PD generating charges in response to external light and a pixel circuit converting the charges generated by the PD into an electrical signal. Image sensors may be widely applied to smartphones, tablet personal computers (PCs), laptop computers, televisions, automobiles, and the like, in addition to cameras for capturing images or video. Recently, research has been conducted to improve the performance of image sensors having a divided PD structure in order to improve a dynamic range of image sensors.

### SUMMARY

The embodiments of the inventive concepts provide an image sensor having improved image quality.

In addition, the problems to be solved by the inventive concepts are not limited to the aforementioned problems, and other problems may be clearly understood to be solved by those skilled in the art from the description below.

Embodiments of the inventive concepts provide an image sensor that includes a substrate including a first photodiode (PD) region and a second PD region adjacent to the first PD region; a first PD having a first area, the first PD in the first PD region; a second PD having a second area smaller than the first area, the second PD in the second PD region; a micro-lens on the substrate and covering the first PD region; and a light splitter between the substrate and the micro-lens, and the light splitter including a material having a refractive index different from a refractive index of the micro-lens. The light splitter extends from the first PD region to the second PD region.

Embodiments of the inventive concepts further provide an image sensor that includes a substrate in which a first photodiode (PD) region and a second PD region are defined; a first PD having a first area in the substrate, the first PD in the first PD region; a second PD in the substrate, the second PD having a second area smaller than the first area, and the second PD in the second PD region; a color filter on the substrate; and a light splitter between the substrate and the color filter, or on the color filter. The light splitter includes a material having a refractive index different from a refractive index of the color filter, and the light splitter vertically overlaps at least a portion of the first PD region and at least a portion of the second PD region.

Embodiments of the inventive concepts still further provide an image sensor that includes a substrate including a first photodiode (PD) region and a second PD region adjacent to the first PD region; a first PD in the first PD region, the first PD having a first area; a second PD in the second PD region, and the second PD having a second area smaller than the first area; a deep trench isolation (DTI) separating the first PD region from the second PD region and passing through the substrate; a micro-lens on the substrate and covering the first PD region; a color filter between the substrate and the micro-lens; a light splitter between the substrate and the color filter, or between the color filter and the micro-lens; and an interconnection layer below the substrate, and the interconnection layer including an insulating film and a conductive interconnection in the insulating film. The light splitter vertically overlaps at least a portion of the first PD region and at least a portion of the second PD region, and the light splitter has a refractive index different from refractive indices of the micro-lens and the color filter.

### BRIEF DESCRIPTION OF THE DRAWINGS

Embodiments will be more clearly understood from the following detailed description taken in conjunction with the accompanying drawings in which:

FIG. 1 is a schematic block diagram of an image processing device including an image sensor according to some example embodiments;

FIGS. 2 and 3 are perspective views schematically illustrating an image processing device including an image sensor according to some example embodiments;

FIG. 4 is a circuit diagram illustrating a pixel circuit included in an image sensor according to some example embodiments;

FIG. 5 is a plan view of an image sensor according to some example embodiments;

FIG. 6 is a diagram of an image sensor according to some example embodiments and is a cross-sectional view of FIG. 5 taken along line A-A′;

FIG. 7 is a plan view of an image sensor according to some example embodiments;

FIG. 8 is a plan view of an image sensor according to some example embodiments;

FIG. 9 is a plan view of an image sensor according to some example embodiments;

FIG. 10 is a plan view of an image sensor according to some example embodiments;

FIG. 11 is a plan view of an image sensor according to some example embodiments;

FIG. 12 is a plan view of an image sensor according to some example embodiments;

FIG. 13 is a plan view of an image sensor according to some example embodiments;

FIG. 14 is a plan view of an image sensor according to some example embodiments;

FIG. 15 is a view of an image sensor according to some example embodiments and is a cross-sectional view of FIG. 14 taken along line B-B′.

FIG. 16 is a diagram of an image sensor according to some example embodiments and is a cross-sectional view of FIG. 5 taken along line A-A′.

FIG. 17 is a diagram of an image sensor according to some example embodiments and is a cross-sectional view of FIG. 5 taken along line A-A′.

FIG. 18 is a plan view of an image sensor according to some example embodiments;

FIG. 19 is a diagram of an image sensor according to some example embodiments and is a cross-sectional view of FIG. 18 taken along line C-C′;

FIG. 20 is a plan view of an image sensor according to some example embodiments;

FIG. 21 is a diagram of an image sensor according to some example embodiments and is a cross-sectional view of FIG. 20 taken along line D-D′;

FIG. 22 is a plan view of an image sensor according to some example embodiments;

FIG. 23 is a plan view of an image sensor according to some example embodiments;

FIG. 24 is a plan view of an image sensor according to some example embodiments;

FIG. 25 is a plan view of an image sensor according to some example embodiments;

FIG. 26 is a view of an image sensor according to some example embodiments and is a cross-sectional view of FIG. 25 taken along line E-E′;

FIG. 27 is a plan view of an image sensor according to some example embodiments;

FIG. 28 is a view of an image sensor according to some example embodiments and is a cross-sectional view of FIG. 27 taken along line F-F′;

FIG. 29 is a plan view of an image sensor according to some example embodiments; and

FIG. 30 is a view of an image sensor according to some example embodiments and is a cross-sectional view of FIG. 29 taken along line G-G′.

### DETAILED DESCRIPTION OF THE EMBODIMENTS

Hereinafter, example embodiments are described in detail with reference to the accompanying drawings. The same reference numerals are used for the same components in the drawings, and redundant descriptions thereof are omitted.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

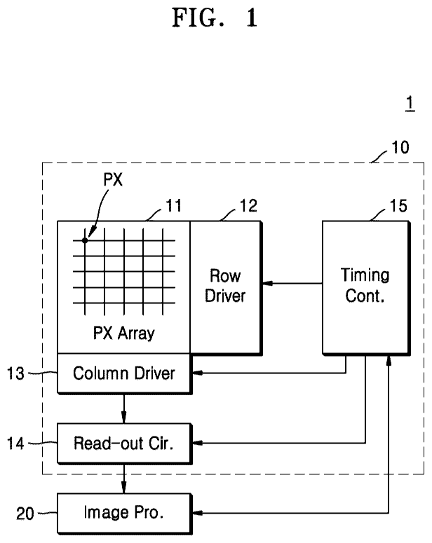

FIG. 1 is a schematic block diagram of an image processing device 1 including an image sensor 10 according to some example embodiments.

Referring to FIG. 1, the image processing device 1 of some example embodiments may include the image sensor 10 and an image processor 20. The image sensor 10 may include a pixel array 11, a row driver 12, a column driver 13, a read-out circuit 14, a timing controller 15, and the like.

The image sensor 10 may operate according to a control command received from the image processor 20, convert light reflected from an object to be imaged into an electrical signal, and output the electrical signal to the image processor 20. The pixel array 11 included in the image sensor 10 may include a plurality of pixels PX, and each of the pixels PX may include a photodiode (PD) generating charges upon receiving light. In some example embodiments, each of the pixels PX may include two or more PDs.

In addition, each of the pixels PX may include a pixel circuit for generating an electrical signal from the charges generated in the PD. For example, the pixel circuit may include a pixel transistor (TR), such as a transfer TR, a driving TR, a select TR, and a reset TR. When one pixel PX has two or more PDs, each pixel PX may include a pixel circuit for processing charges generated in each of the two or more PDs. That is, when one pixel PX has two or more PDs, the pixel circuit may include two or more of at least one of the transfer TR, the driving TR, the select TR, and the reset TR.

In the image processing device 1 of some example embodiments, one pixel PX may include two PDs. Accordingly, the pixel PX may have a split PD structure. In addition, in the image processing device 1 of some example embodiments, one pixel PX may include a first pixel circuit processing a charge generated by one PD and a second pixel circuit processing a charge generated by another PD. Each of the first pixel circuit and the second pixel circuit may include a plurality of semiconductor devices. The first pixel circuit may generate a first pixel signal from the charge generated by one PD and output the first pixel signal, and the second pixel circuit may generate a second pixel signal from the charge generated by another PD and output the second pixel signal. Each of the first pixel signal and the second pixel signal may include a reset voltage and a pixel voltage.

The row driver 12 may drive the pixel array 11 in units of rows. For example, the row driver 12 may generate a transfer control signal for controlling the transfer TR of each pixel PX, a reset control signal for controlling the reset TR of each pixel PX, and a select control signal for controlling the select TR of each pixel PX.

The column driver 13 may include a correlated double sampler (CDS), an analog-to-digital converter (ADC), and the like. The CDS may perform correlated double sampling to acquire pixel signals through column lines connected to pixels PXs included in a row selected by a row select signal supplied from the row driver 12. The ADC may convert an output from the CDS into a digital signal and transfer the digital signal to the read-out circuit 14.

The read-out circuit 14 may include a latch or buffer circuit for temporarily storing a digital signal and an amplifier circuit. In addition, the read-out circuit 14 may process the digital signal received from the column driver 13 to generate image data. Operation timings of the row driver 12, the column driver 13, and the read-out circuit 14 may be determined by the timing controller 15. The timing controller 15 may operate according to a control command transferred from the image processor 20. The image processor 20 may process image data output from the read-out circuit 14 and output the image data to a display device or the like or store the image data in a storage device, such as a memory. In addition, when the image processing device 1 of some example embodiments is mounted in an autonomous vehicle, the image processor 20 may signal-process the image data and transmit the image data to a main controller that controls the autonomous vehicle.

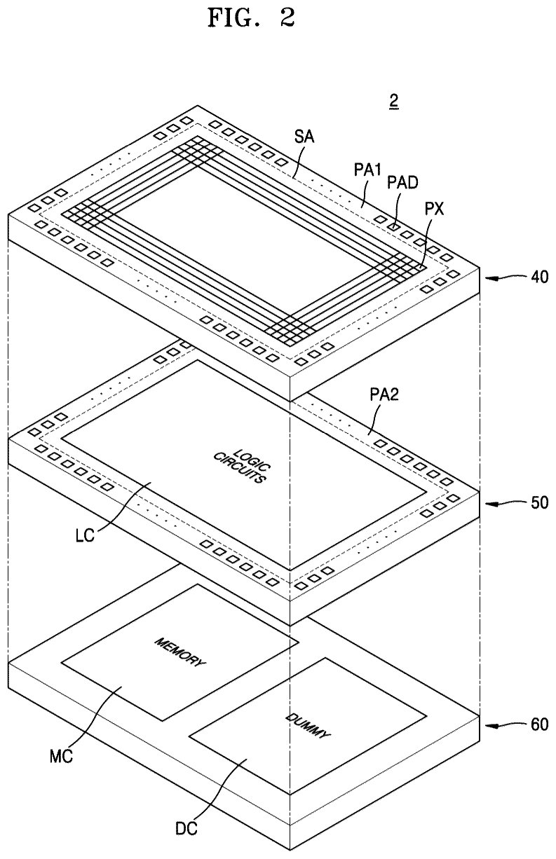

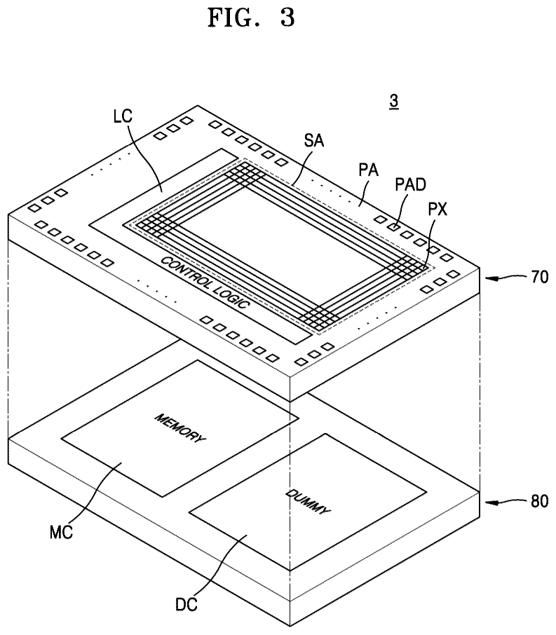

FIGS. 2 and 3 are perspective views schematically illustrating an image processing device including an image sensor according to an embodiment.

Referring to FIG. 2, the image processing device 2 of some example embodiments may include a plurality of stacked chips. For example, the image processing device 2 may include an upper chip 40 including a sensing region SA, a middle chip 50 including a logic circuit region LC, and a lower chip 60 having a memory region MC and a dummy region DC. In some example embodiments, the upper chip 40 may be stacked on the middle chip 50 at a wafer level, and the lower chip 60 may be attached to a lower portion of the middle chip 50 at a chip level.

The upper chip 40 may include the sensing region SA in which a plurality of pixels PX are arranged and a first pad region PA1 around the sensing region SA. A plurality of upper pads PAD may be arranged in the first pad region PA1. The upper pads PAD may be connected to pads arranged in a second pad region PA2 of the middle chip 50 through vias or the like to be connected to logic circuits of the logic circuit region LC.

Each of the pixels PX may include a PD generating a charge upon receiving light and a pixel circuit converting the charge generated in the PD into an electrical signal. The PD may include an organic PD, a semiconductor PD, and the like. In some example embodiments, each of the pixels PX may include a plurality of semiconductor PDs. The pixel circuit may include a plurality of pixel TRs for converting the charge generated in the PD into an electrical signal.

The middle chip 50 may include the logic circuit region LC in which logic circuits are arranged and the second pad region PA2 around the logic circuit region LC. The logic circuits of the logic circuit region LC may include circuits for driving the pixel circuit located in the upper chip 40, for example, a row driver, a column driver, and a timing controller. The logic circuits of the logic circuit region LC may be connected to the pixel circuit through pads of the first and second pad regions PA1 and PA2 and vias.

The lower chip 60 may include the memory region MC and the dummy region DC. In some example embodiments, the dummy region DC may be omitted. In addition, in some embodiments, the lower chip 60 may have a package structure. For example, as each of the memory region MC and the dummy region DC is manufactured as a chip and sealed together with a sealing material, the lower chip 60 may have a package structure including two chips. The memory devices, such as dynamic random access memory (DRAM) devices or static random access memory (SRAM) devices, may be arranged in the memory region MC. However, the memory devices arranged in the memory region MC are not limited to DRAM devices or SRAM devices. Memory devices may not be arranged in the dummy region DC. The dummy region DC may have a function of supporting the upper chips 40 and 50, rather than a function of storing data. The memory devices of the memory region MC may be electrically connected to at least some of the logic circuits of the logic circuit region LC of the middle chip 50 through bumps or through-electrodes.

Referring to FIG. 3, an image processing device 3 of some example embodiments may include an upper chip 70 and a lower chip 80. The upper chip 70 may include a sensing region SA provided with a plurality of pixels PX, a logic circuit region LC provided with devices for driving a plurality of pixels PX, and a pad region PA around the sensing region SA and the logic circuit region LC. A plurality of upper pads PAD may be arranged in the pad region PA, and the upper pads PAD may be connected to memory devices of a memory region MC provided in the lower chip 80 through vias or the like. The lower chip 80 may include the memory region MC and a dummy region DC. The lower chip 80 may be substantially the same as the lower chip 60 of the image processing device 2 of FIG. 2. Accordingly, a detailed description of the lower chip 80 is omitted.

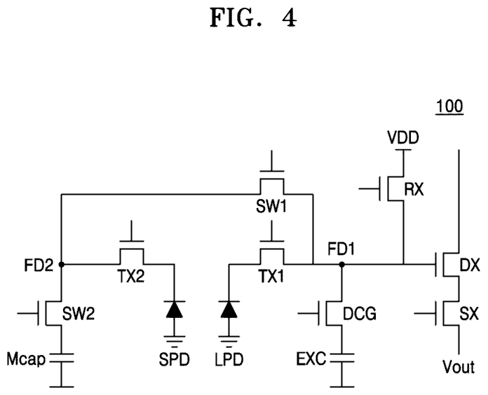

FIG. 4 is a circuit diagram illustrating a pixel circuit included in an image sensor 100 according to some example embodiments.

Referring to FIG. 4, the pixel circuit of the image sensor 100 of the present embodiment may include a first PD (LPD), a second PD (SPD), a first transfer TR (TX1), a second transfer TR (TX2), a first floating diffusion (FD) (FD1), a second FD (FD2), a first switch SW1, a second switch SW2, a reset TR (RX), a driving TR (DX), a select TR (SX), a metal capacitor Mcap, a capacitor EXC, and a dual conversion gain TR (DCG).

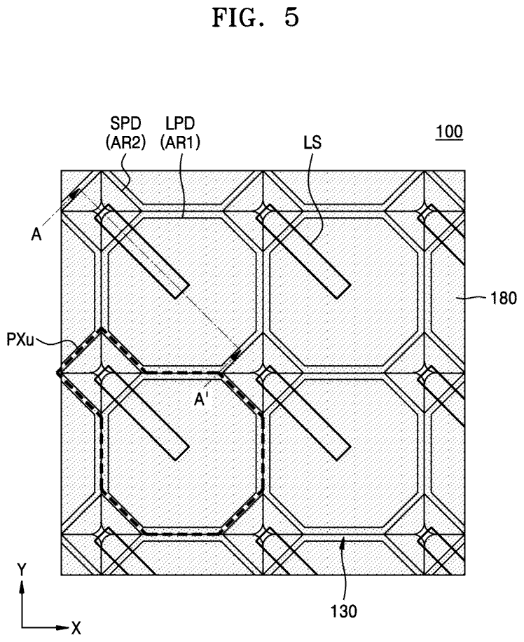

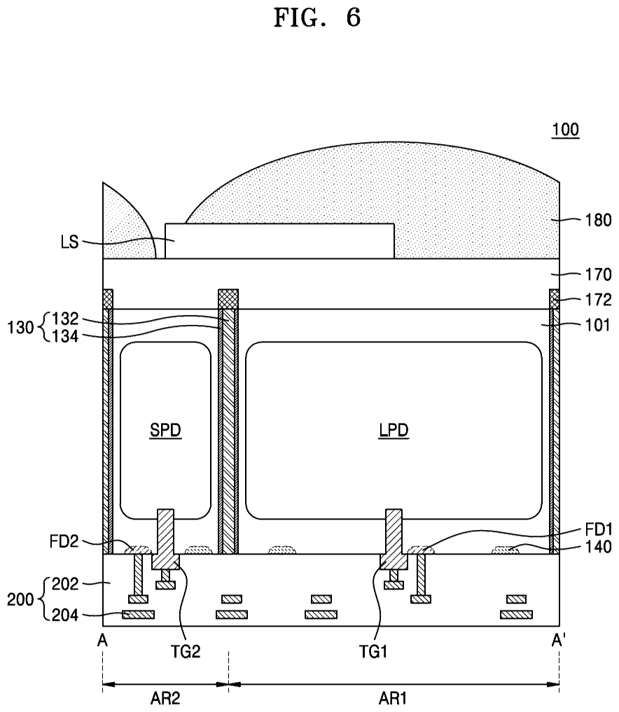

The first PD (LPD) and the second PD (SPD) may be photodiodes including an n-type impurity region and a p-type impurity region. According to the pixel circuit of the image sensor 100, electric signals may be output using charges generated by the first PD (LPD) and the second PD (SPD). The first PD (LPD) may have, for example, several to several tens of times the size of the second PD (SPD). Here, the size may refer to a horizontal area. For example, the horizontal area of the first PD (LPD) may refer to an area over which the first PD (LPD) extends along a plane parallel to the upper surface of the substrate 101 (e.g., see FIG. 6), or in other words the area of the first PD (LPD) when viewed in top plan view. Accordingly, as can be seen from FIGS. 5 and 6, the first PD (LPD) may have a light-receiving area several to several tens of times greater than that of the second PD (SPD).

The first PD (LPD) may be connected to the first FD (FD1) through the first transfer TR (TX1). The first transfer TR (TX1) may transfer charges accumulated in the first PD (LPD) to the first FD (FD1) based on a transmission control signal transferred from a row driver. The first PD (LPD) may generate electrons as primary charge carriers.

The second PD (SPD) may be connected to the second FD (FD2) through the second transfer TR (TX2). The second transfer TR (TX2) may transfer charges accumulated in the second PD (SPD) to the second FD (FD2) based on a transmission control signal transferred from the row driver. The second PD (SPD) may also generate electrons as main charge carriers. For example, charges generated in the second PD (SPD) may move to the second FD (FD2) when the second transfer TR (TX2) is turned on. The second PD (SPD) may generate charges in response to light while the second transfer TR (TX2) is in an OFF state, and each time the second transfer TR (TX2) is turned on, charges generated in the second PD (SPD) may move from the second PD (SPD) to the second FD (FD2) to be accumulated therein.

In some example embodiments, a conversion gain (CG) of charges generated in the first PD (LPD) or capacitance of a pixel may be adjusted using the first switch SW1 and the second FD (FD2). The first switch SW1 may be implemented as a TR. For example, the first FD (FD1) may be combined with the second FD (FD2) by turning on the first switch SW1, thereby increasing the capacity the pixel to increase a dynamic range (DR) and change a CG. That is, the image sensor 100 of some example embodiments may have a double CG structure.

Also, the charge generated in the second PD (SPD) may be stored in the metal capacitor Mcap. The second switch SW2 may be located between the metal capacitor Mcap and the second FD FD2. The second switch SW2 may also be implemented as a TR, like the first switch SW1. Accordingly, the metal capacitor Mcap may store charges in response to the operation of the second transfer TR (TX2) and the second switch SW2. According to some example embodiments, the second switch SW2 may not be provided. According to some example embodiments, without the second switch SW2, the metal capacitor Mcap may store charges in response to an operation of the second transfer TR (TX2).

In addition, a first switch SW1 and a second switch SW2 may be located between the metal capacitor Mcap and the first FD FD1. Accordingly, charges of the metal capacitor Mcap may move to the first FD FD1 by an ON/OFF operation of the first switch SW1 and the second switch SW2. As described above, the second PD (SPD) has a relatively small light-receiving area compared to the first PD (LPD), and saturation of the second PD (SPD) may be limited or prevented by moving charges of the second PD (SPD) to be stored in the metal capacitor Mcap.

In the image sensor 100 of some example embodiments, the second PD (SPD) may be used for the purpose of improving the dynamic range (DR) of the image sensor 100. That is, by using the metal capacitor Mcap, it is possible to store and output charges without the image sensor 100 being saturated even at high illumination.

The driving TR (DX) may operate as a source follower buffer amplifier by the charges accumulated in the first FD (FD1). The driving TR (DX) may amplify the charges accumulated in the first FD (FD1) and transfer a signal to the select TR (SX). For example, the first FD (FD1) may be connected to a gate of the driving TR (DX), and the power supply voltage (VDD) may be connected to sources of the reset TR (RX) and the driving TR (DX). A column line may be connected to a drain of the select TR (SX) so that a voltage Vout may be output. The select TR (SX) is operated by a select control signal input from the row driver and may perform switching and addressing operations. When the select control signal from the row driver is applied to a gate of the select TR (SX), the voltage Vout may be output through the column line connected to the select TR (SX). The voltage Vout may be detected by a column driver and a read-out circuit connected to the column line.

The column driver and read-out circuit may detect a reset voltage in a state in which charges are not accumulated in the first FD (FD1), and detect a pixel voltage in a state in which charges are accumulated in the first FD (FD1). The image sensor 100 of some example embodiments may generate image data by calculating a difference between the reset voltage and the pixel voltage using the CDS included in the column driver 13 illustrated in FIG. 1, for example.

The dual conversion gain TR (DCG) may be coupled with a capacitor EXC. The first FD (FD1) may or may not be connected to the capacitor EXC according to an ON or OFF state of the dual conversion gain TR (DCG). Through this, the capacitance of the first FD (FD1) may be adjusted. When the dual conversion gain TR (DCG) is turned off, the capacitance of the first FD (FD1) may be reduced to increase a CG, thereby improving performance of image sensor 100 in low-light amount condition. When the dual conversion gain TR (DCG) is turned on, the capacitance of the first FD (FD1) may increase to increase a charge storage capacity (or a full well capacity), so that of image sensor 100 may be improved in high-light amount condition. In this manner, the dual conversion gain TR (DCG) may perform a function of improving the image quality of the image sensor 100 by dynamically adjusting ON/OFF in low-light amount and high-light amount conditions.

The first PD (LPD) may share the column line with the second PD (SPD). Accordingly, while the first pixel voltage corresponding to the charges of the first PD (LPD) is output through the column line, the second PD (SPD) may be separated from the column line. For example, while the first pixel voltage is output to the column line, the second PD (SPD) may be separated from the column line by turning off at least one of the second transfer TR (TX2) and the first switch SW1. In order to generate the first pixel voltage using the charges of the first PD (LPD) and output the first pixel voltage to the column line, the charges generated in the first PD (LPD) as the first transfer TR (TX1) is turned on may be accumulated in the first FD (FD1).

Similarly, while a second pixel voltage corresponding to the charges of the second PD (SPD) is output to the column line, the first PD (LPD) may be separated from the column line. For example, while the second pixel voltage is output to the column line, the first transfer TR (TX1) may be turned off to separate the first PD (LPD) from the column line. In order to generate the second pixel voltage using the charges of the second PD (SPD) and output the second pixel voltage to the column line, the second transfer TR (TX2) and the first switch SW1 may be turned on to connect the first FD (FD1) to the second FD (FD2). The charges of the second PD (SPD) may be accumulated in the first FD (FD1) and the second FD (FD2) and converted into a voltage by the driving TR (DX).

FIG. 5 is a plan view of the image sensor 100 according to some example embodiments. FIG. 6 is a diagram of the image sensor 100 according to some example embodiments and is a cross-sectional view of FIG. 5 taken along line A-A′.

Referring to FIGS. 5 and 6, the image sensor 100 may include a substrate 101, a first PD (LPD), a second PD (SPD), a deep trench isolation (DTI) 130, a metal grid 172, a color filter 170, a light splitter LS, a micro-lens 180, and an interconnection layer 200.

The substrate 101 may include silicon. However, the material of the substrate 101 is not limited to silicon. For example, the substrate 101 may include a single-element semiconductor, such as germanium (Ge), or a compound semiconductor, such as silicon carbide (SiC), gallium arsenide (GaAs), indium arsenide (InAs), or indium phosphide (InP).

A plurality of unit pixels PXu may be arranged in a two-dimensional array structure in a first direction X and a second direction Y. In the present specification, the first direction X is a direction parallel to an upper surface of the substrate 101, and the second direction Y is a direction parallel to the upper surface of the substrate 101 and perpendicular to the first direction X.

Each of the unit pixels PXu may include one first PD region AR1 and one second PD region AR2 corresponding to the one first PD region AR1. For example, the unit pixel PXu may include one first PD region AR1, and one second PD region AR2 arranged on the upper left portion of the one first PD region AR1 (e.g., at a location near a corner area of the one first PD region AR1). The unit pixels PXu may be separated from each other by the DTI 130 structure. The first PD region AR1 and the second PD region AR2 may be separated from each other by the DTI 130 structure.

For example, the unit pixels PXu may be separated from each other by a front-DTI structure.

In a plan view, the first PD region AR1 may have an octagonal shape, and the second PD region AR2 may have a quadrangular shape. In addition, the second PD region AR2 may be located between four first PD regions AR1 adjacent to the second PD region AR2. For example, one second PD region AR2 may be surrounded by four first PD regions AR1. In addition, four second PD regions AR2 may be alternately located to be adjacent to four of the eight sides of the first PD region AR1.

In some example embodiments, the first PD region AR1 may have an octagonal shape and the second PD region AR2 may have a quadrangular shape as described. However, in some other example embodiments the shapes of the first PD region AR1 and the second PD region AR2 constituting each of the unit pixels PXu are not limited to the shapes described above. For example, the first PD region AR1 may have a quadrangular or hexagonal shape. Moreover, the second PD region AR2 may have a quadrangular shape. For example, the second PD region AR2 may also be disposed inside the first PD region AR1. In this case, the second PD region AR2 may have various shapes, such as circular, elliptical, or polygonal, other than quadrangular. The shape may vary depending on the design of the image sensor 100 to be implemented.

The first PD (LPD) may be disposed within the substrate 101 in the first PD region AR1, and the second PD (SPD) may be disposed within the substrate 101 in the second PD region AR2. Furthermore, the first PD region AR1 may be separated from the second PD region AR2 by the DTI 130.

The DTI 130 may pass through the substrate 101 in a vertical direction. As the DTI 130 is formed in a structure passing through the substrate 101, crosstalk between pixels due to obliquely incident light may be limited or prevented. In addition, each of the first PD (LPD) and the second PD (SPD) may be formed to be substantially adjacent to the DTI 130, and accordingly, a light receiving area may be enlarged to improve a fill factor.

The DTI 130 may include a conductive layer 132 and an insulating film 134. The conductive layer 132 may include, for example, polysilicon or polysilicon doped with impurities. However, the material of the conductive layer 132 is not limited to the above materials. For example, the conductive layer 132 may include metal, metal silicide, or a metal-containing conductive material. The insulating film 134 may surround the outside of the conductive layer 132 and insulate the conductive layer 132 from the substrate 101. The insulating film 134 may include, for example, oxide or nitride, such as silicon oxide, silicon nitride, and silicon oxynitride. However, the material of the insulating film 134 is not limited to the above materials.

The color filter 170 may be disposed on the upper surface of the substrate 101. The color filter 170 may cover an upper surface of the substrate 101. The color filter 170 may include any one of a red filter, a blue filter, and a green filter. In some example embodiments, the color filter 170 may be omitted. When the color filter 170 is omitted, another transparent structure allowing light to be transferred therethrough may be included where the color filter 170 may have been. When the color filter 170 is omitted, the image sensor 100 may be used as an infrared sensor.

The metal grid 172 may be located between the substrate 101 and the color filter 170. The metal grid 172 may vertically overlap the DTI 130. A vertical thickness of the metal grid 172 may be less than a vertical thickness of the color filter 170. However, the inventive concepts are not limited thereto, and a vertical thickness of the metal grid 172 may be the same as a vertical thickness of the color filter 170. The vertical thickness refers to a thickness in a direction perpendicular to the upper surface of the substrate 101.

The metal grid 172 may separate the color filters 170 from each other. The metal grid 172, along with the DTI 130, may limit or prevent light incident on the color filter 170 from being transferred to the PD of the adjacent unit pixel PXu. Accordingly, the occurrence of crosstalk between the unit pixels PXu of the image sensor 100 may be reduced. The metal grid 172 may include a conductive material, such as metal and/or metal nitride. For example, the metal grid 172 may include tungsten (W), titanium (Ti), and/or titanium nitride (TIN). However, the material of the metal grid 172 is not limited to W, Ti, and TiN. A grid structure including a low refractive index material may be additionally formed on the metal grid 172.

A light splitter LS may be disposed on the color filter 170. In a plan view, the light splitter LS may have a quadrangular shape. The light splitter LS may have a long axis extending in a direction from the center of the first PD region AR1 to the center of the second PD region AR2 in a plan view. The light splitter LS may extend from the first PD (LPD) onto the second PD (SPD) without being disconnected. The light splitter LS may vertically overlap at least a portion of the first PD (LPD) and may vertically overlap at least a portion of the second PD (SPD).

The light splitter LS may include a material having a refractive index different from that of the color filter 170 and the micro-lens 180. For example, the light splitter LS may include at least one of TiO₂, SiO₂, SiN, and amorphous silicon.

On the color filter 170, the micro-lens 180 may vertically overlap the first PD region AR1. The micro-lens 180 may vertically overlap the entirety of the first PD region AR1 and may vertically overlap a portion of the second PD region AR2. Another portion of the second PD region AR2 may not vertically overlap the micro-lens 180.

On the first PD region AR1, the micro-lens 180 may cover the color filter 170 and the light splitter LS. On the second PD region AR2, the micro-lens 180 may cover at least a portion of the color filter 170 and at least a portion of the light splitter LS. Accordingly, a portion of an upper surface of the color filter 170 and a portion of an upper surface of the light splitter LS may be exposed to the outside from the micro-lens 180. Alternatively, the micro-lens 180 may cover an entirety of light splitter LS on the second PD region AR2. This may vary depending on the design of the image sensor 100 to be implemented. The micro-lens 180 may have a dome shape or a hemispherical shape.

In some example embodiments, on the second PD region AR2, the micro-lens 180 may completely cover the color filter 170 and the light splitter LS or may not cover at least a portion of each of the color filter 170 and the light splitter LS. A horizontal area of the micro-lens 180 may vary. This may vary depending on the design of the image sensor 100 to be implemented.

The micro-lens 180 may be transparent so that light may be transferred through the micro-lens 180. The micro-lens 180 may include an organic material, such as a polymer. For example, the micro-lens 180 may include a photoresist material or a thermosetting resin.

External light may pass through the micro-lens 180. Light transferred through the micro-lens 180 may travel to the first PD (LPD) through the color filter 170 or may be incident on the light splitter LS. Part of the light traveling to the light splitter LS may be repeatedly reflected from an interface between the light splitter LS and the micro-lens 180 and an interface between the light splitter LS and the color filter 170. In this way, the part of the light traveling to the light splitter LS may travel from the first PD (LPD) to the second PD (SPD). Light traveling onto the second PD (SPD) may exit the light splitter LS and may be incident on the second PD (SPD). That is, the light splitter LS, as its name suggests, may perform a function of distributing light incident on the first PD region AR1 to the second PD region AR2.

Without the light splitter LS, if the micro-lens 180 covering the first PD region AR1 and the micro-lens 180 covering the second PD region AR2 are provided separately, the two micro-lenses 180 inevitably have different heights. This is because the micro-lens 180 may have a dome shape or a hemispherical shape. In this case, when an angle of light incident on the two micro-lenses 180 increases based on the direction perpendicular to the upper surface of the substrate 101, the degree of vignetting that occurs in the first PD region AR1 and the second PD region AR2 may vary, and thus, relative illumination in the first PD (LPD) and the second PD (SPD) may vary. In addition, considering that the first PD (LPD) and the second PD (SPD) constitute one unit pixel PXu in the image sensor 100, optical centers may not match each other due to a difference in position of the first PD (LPD) and the second PD (SPD). In addition, the optical center mismatch may cause color separation between the first PD (LPD) and the second PD (SPD). In addition, if the heights of the two micro-lenses 180 are different, the micro-lens of the first PD (LPD) covers the micro-lens of the second PD (SPD) as the angle of the incident light increases, so that optical characteristics of the first PD (LPD) and the second PD (SPD) may vary.

The image sensor 100 according to the inventive concepts may include the substrate 101 including the first PD (LPD) and the second PD (SPD), the light splitter LS on the substrate 101, and the micro-lens 180 on the light splitter LS. The light splitter LS may include a material having a refractive index different from that of the micro-lens 180. As a result, light incident on the first PD (LPD) may be incident on the light splitter LS through the micro-lens 180 and incident on the second PD (SPD) through the light splitter LS. Therefore, because only one micro-lens 180 may be located in the unit pixel PXu, problems that may be caused due to different heights of the micro-lenses 180 may be limited, reduced or prevented. For the above reasons, the image quality of the image sensor 100 may be improved.

Pixel circuits may be arranged below the substrate 101. The rest of the pixel circuits, not shown, may be arranged outside or inside in a direction perpendicular to a paper plane of FIG. 6. For example, referring to only the illustrated pixel circuits, a gate TG1 of the first transfer TR (TX1 in FIG. 4) and the first FD (FD1) may be located in a lower portion of the substrate 101 in the first PD region AR1. A gate TG2 of the second transfer TR (TX2 in FIG. 4) and the second FD (FD2) may be located in a lower portion of the substrate 101 in the second PD region AR2.

The gate TG1 of the first transfer TR (TX1 in FIG. 4) and the gate TG2 of the second transfer TR (TX2 in FIG. 4) may have a vertical structure. Accordingly, the gate TG1 of the first transfer TR (TX1 in FIG. 4) may extend to vertically pass through the lower portion of the substrate 101 to be connected to the first PD (LPD). The gate TG2 of the second transfer TR (TX2 in FIG. 4) may extend to vertically pass through the lower portion of the substrate 101 to be connected to the second PD (SPD). The gate TG1 of the first transfer TR (TX1 in FIG. 4) and the gate TG2 of the second transfer TR (TX2 in FIG. 4) may include a conductive material, such as doped silicon.

Although not shown, a gate of the reset TR (RX in FIG. 4), the gate of the driving TR (DX in FIG. 4), and the gate of the select TR (SX in FIG. 4) may have a horizontal structure. Accordingly, the gates of the horizontal structure may be located on a lower surface of the substrate 101.

In addition, a plurality of heavily-doped regions 140 may be arranged on the lower surface of the substrate 101. The heavily-doped regions 140 may include the first FD (FD1), the second FD (FD2), and source/drain regions of the pixel TRs. For example, the heavily-doped region 140 on the side of the gate TG1 of the first transfer TR (TX1 in FIG. 4) may constitute the first FD (FD1). Similarly, the heavily-doped region 140 on the side of the gate TG2 of the second transfer TR (TX2 in FIG. 4) may constitute the second FD (FD2). Although not shown, the highly-doped regions 140 on both sides of the gate of the driving TR (DX in FIG. 4) and the gate of the select TR (SX in FIG. 4) may constitute the source/drain regions of the driving TR (DX in FIG. 4) and the select TR (SX in FIG. 4).

The interconnection layer 200 may be disposed on the lower surface of the substrate 101. The interconnection layer 200 may include an insulating film 202 and a conductive interconnection 204 within the insulating film 202. The conductive interconnection 204 may be connected to the gate TG1 of the first transfer TR (TX1 in FIG. 4), the gate TG2 of the second transfer TR (TX2 in FIG. 4), the first FD (FD1), and the second FD (FD2). The conductive interconnection 204 may also be connected to other pixel circuits not shown in FIG. 6.

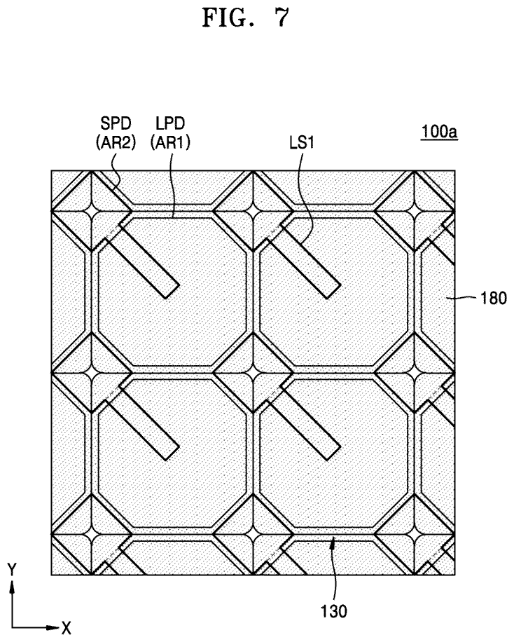

FIGS. 7 to 13 are plan views of image sensors 100a to 100g according to some example embodiments. Hereinafter, the same descriptions as those given above with reference to FIGS. 5 and 6 are omitted, and only differences are described in detail.

Referring to FIGS. 7 to 13, a planar shape of the light splitter LS may be variously modified. Referring to FIG. 7, a horizontal area of a light splitter LS1 of the image sensor 100a in the second PD region AR2 may be greater than a horizontal area thereof in the edge of the first PD region AR1. The edge of the first PD region AR1 may be a portion (e.g., edge portion) surrounding the center (e.g., center portion) of the first PD region AR1. For example, the light splitter LS1 may cover the entire second PD region AR2. When the horizontal area of the light splitter LS1 in the second PD region AR2 is greater than the horizontal area thereof in the edge of the first PD region AR1, the ratio of light traveling to the second PD region AR2 to light incident on the second PD (SPD) may increase. Accordingly, the efficiency of light transmission to the second PD (SPD) may increase, thereby improving sensitivity of the second PD (SPD).

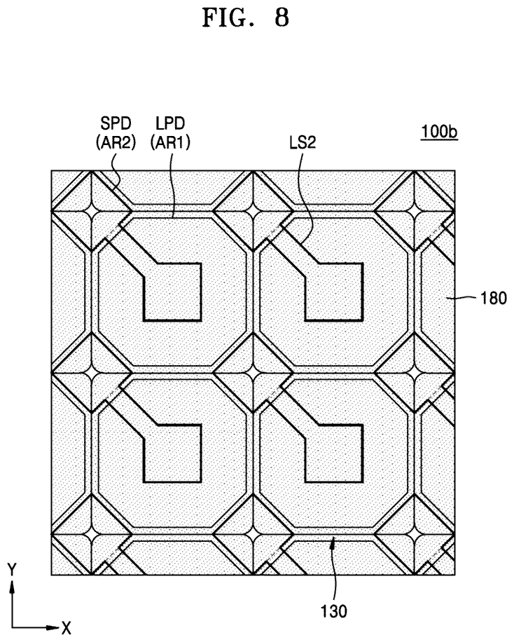

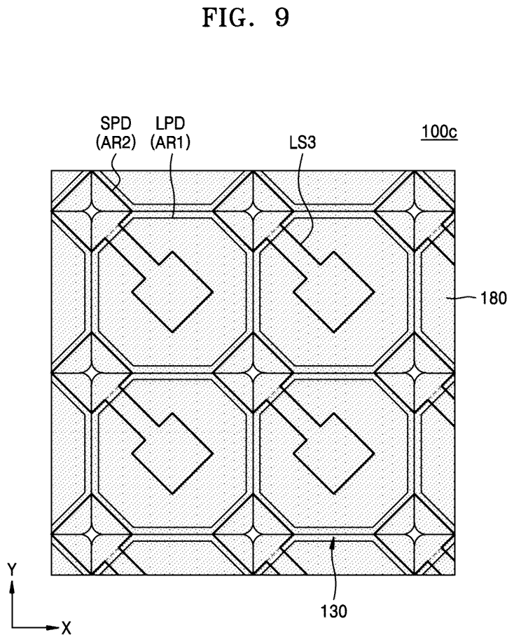

Referring to FIGS. 8 and 9, the horizontal area of light splitters LS2 and LS3 of the image sensors 100b and 100c in the second PD region AR2 may be greater than the horizontal area thereof at the edge of the first PD region AR1. The edge of the first PD region AR1 may be a portion surrounding the center of the first PD region AR1. For example, the light splitters LS2 and LS3 may cover the entire second PD region AR2.

Also, the horizontal area of the light splitters LS2 and LS3 at the center of the first PD region AR1 may be greater than the horizontal area thereof at the edge of the first PD region AR1. For example, the light splitters LS2 and LS3 may have a quadrangular planar shape at the center of the first PD region AR1. Here, a direction of the corner of the quadrangle may be modified in various manners. As shown in FIG. 8, the horizontal side of the quadrangle may be parallel to the first direction X or the second direction Y. Alternatively, as shown in FIG. 9, the horizontal side of the quadrangle may be parallel to the upper surface of the substrate (101 in FIG. 6) and may be parallel to a certain direction crossing the first direction X and the second direction Y. For example, as shown in FIG. 9, the quadrangle may have a rhombic shape. However, the inventive concepts are not limited thereto, and at the center of the first PD region AR1, the light splitters LS2 and LS3 may have various planar shapes, such as circular, elliptical, and polygonal.

In this case, the amount of light incident on the light splitters LS2 and LS3 may increase, so that the ratio of light incident on the first PD region AR1 to light traveling to the second PD region AR2 may increase. Accordingly, the sensitivity of the second PD (SPD) may be improved.

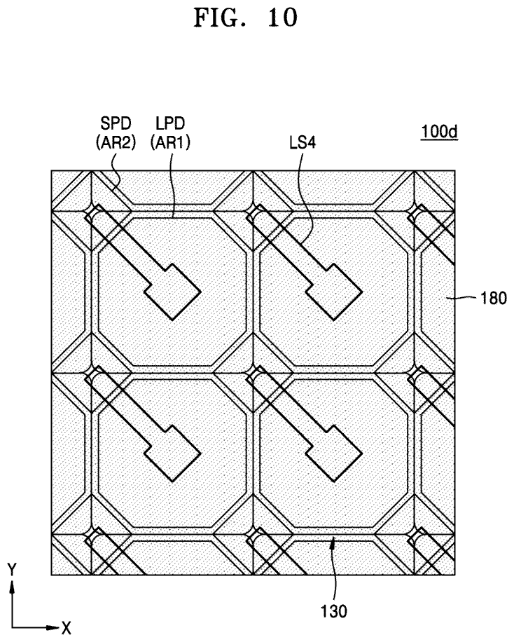

Referring to FIG. 10, image sensor 100d may include a light splitter LS4. A horizontal area of a light splitter LS4 at the center of the first PD region AR1 may be greater than a horizontal area thereof at the edge of the first PD region AR1. The edge of the first PD region AR1 may be a portion surrounding the center of the first PD region AR1. As described above with reference to FIG. 5, the light splitter LS4 may vertically overlap a portion of the second PD region AR2. The light splitter LS4 may not cover at least a portion of the second PD region AR2. For example, the light splitter LS4 may have a quadrangular planar shape at the center of the first PD region AR1. However, the inventive concepts are not limited thereto, and the light splitter LS4 may have various planar shapes, such as circular, elliptical, and polygonal at the center of the first PD region AR1.

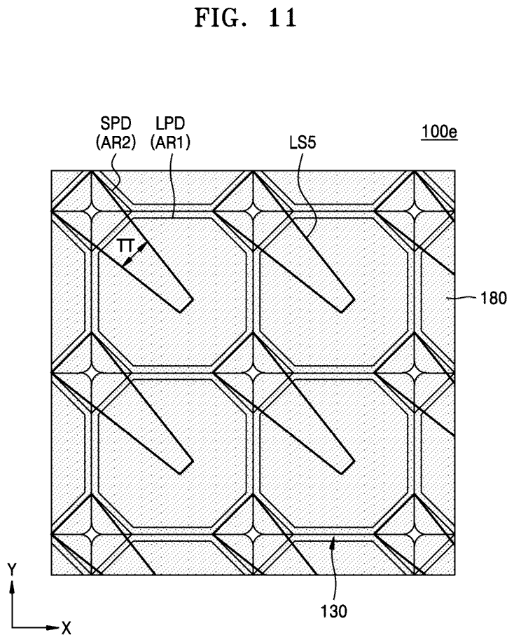

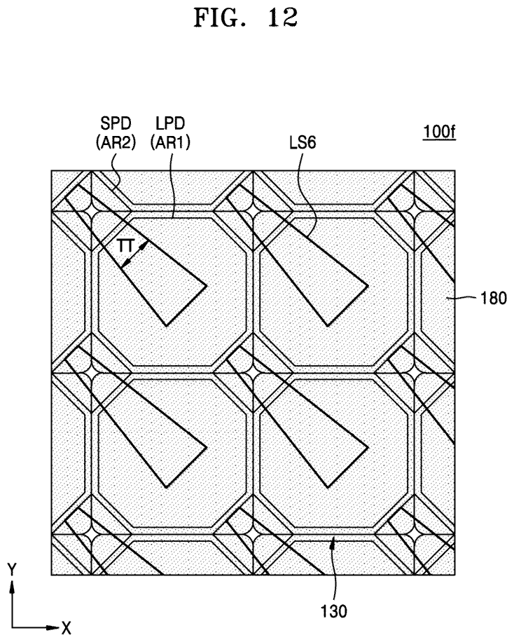

Referring to FIGS. 11 and 12, a thickness TT of a light splitters LS5 and LS6 of the image sensors 100e and 100f may vary in a direction from the center of the first PD region AR1 to the center of the second PD region AR2.

Referring to FIG. 11, the thickness TT of the light splitter LS5 of the image sensor 100e may gradually increase in a direction from the center of the first PD region AR1 to the center of the second PD region AR2. The thickness TT of the light splitter LS5 refers to a direction parallel to the upper surface of the substrate (101 in FIG. 6) and perpendicular to a direction from the center of the first PD region AR1 to the center of the second PD region AR2. As an example, the thickness TT of the light splitter LS5 may increase constantly in a direction from the center of the first PD region AR1 to the center of the second PD region AR2. In FIG. 11, a sidewall of the light splitter LS5 is shown as a straight line, but the inventive concepts are not limited thereto. The sidewall of the light splitter LS5 may have a curved shape.

Referring to FIG. 12, the thickness TT of the light splitter LS6 of the image sensor 100f may gradually decrease in a direction from the center of the first PD region AR1 to the center of the second PD region AR2. The thickness TT of the light splitter LS6 refers to a thickness in a direction parallel to the upper surface of the substrate (101 in FIG. 6) and perpendicular to the direction from the center of the first PD region AR1 to the center of the second PD region AR2. As an example, the thickness TT of the light splitter LS6 may constantly decrease in a direction from the center of the first PD region AR1 to the center of the second PD region AR2. In FIG. 12, the sidewall of the light splitter LS6 is shown as a straight line, but the inventive concepts are not limited thereto. The sidewall of the light splitter LS6 may have a curved shape.

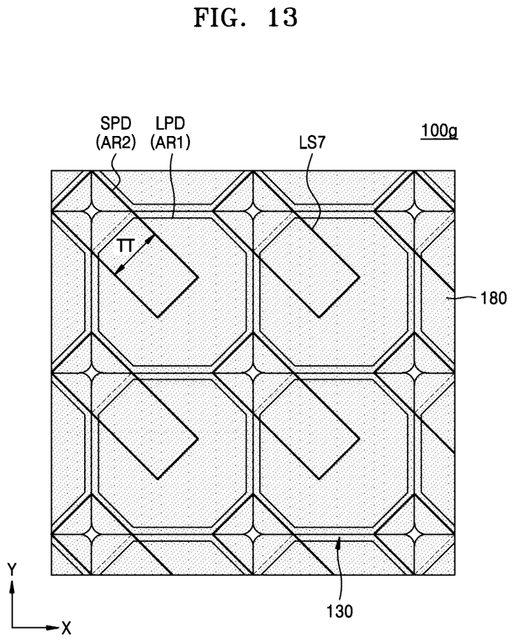

Referring to FIG. 13, a light splitter LS7 of the image sensor 100g may cover the entire second PD region AR2. The thickness TT of the light splitter LS7 may be constant from the center of the first PD region AR1 to the center of the second PD region AR2. The thickness TT of the light splitter LS7 refers to a thickness in a direction parallel to the upper surface of the substrate (101 in FIG. 6) and perpendicular to the direction from the center of the first PD region AR1 to the center of the second PD region AR2.

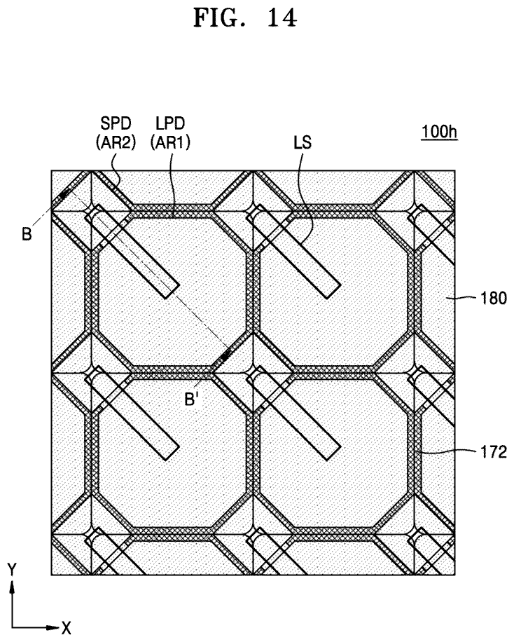

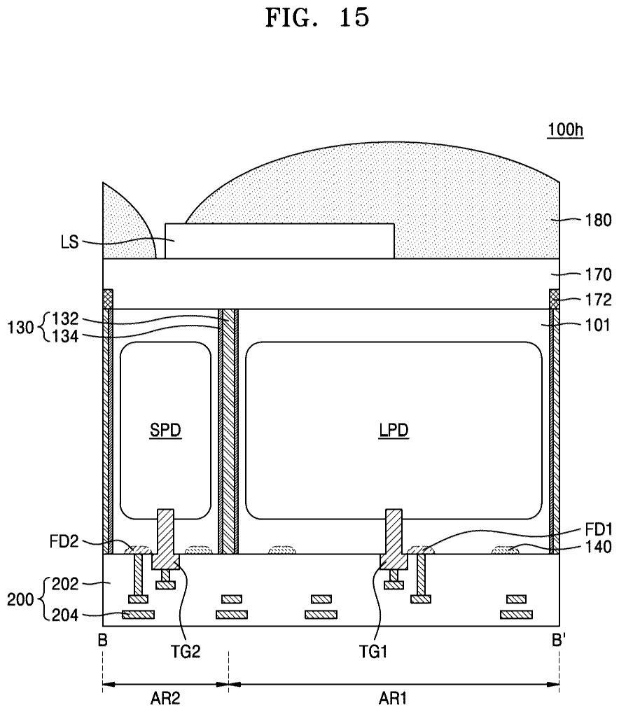

FIG. 14 is a plan view of an image sensor 100h according to some example embodiments. FIG. 15 is a view of the image sensor 100h according to some example embodiments and is a cross-sectional view of FIG. 14 taken along line B-B′. Hereinafter, the same descriptions as those given above with reference to FIGS. 5 and 6 are omitted, and only differences are described in detail.

Referring to FIGS. 14 and 15, at least a portion of the metal grid 172 at the interface between the first PD region AR1 and the second PD region AR2 of the image sensor 100h may be omitted. The metal grid 172 may be omitted in a portion vertically overlapping the light splitter LS. In other words, in a plan view, the metal grid 172 may be apart from the light splitter LS. In this case, even if the metal grid 172 is higher, light may smoothly travel onto the second PD region AR2 through the light splitter LS. Accordingly, the sensitivity of the second PD (SPD) may be improved.

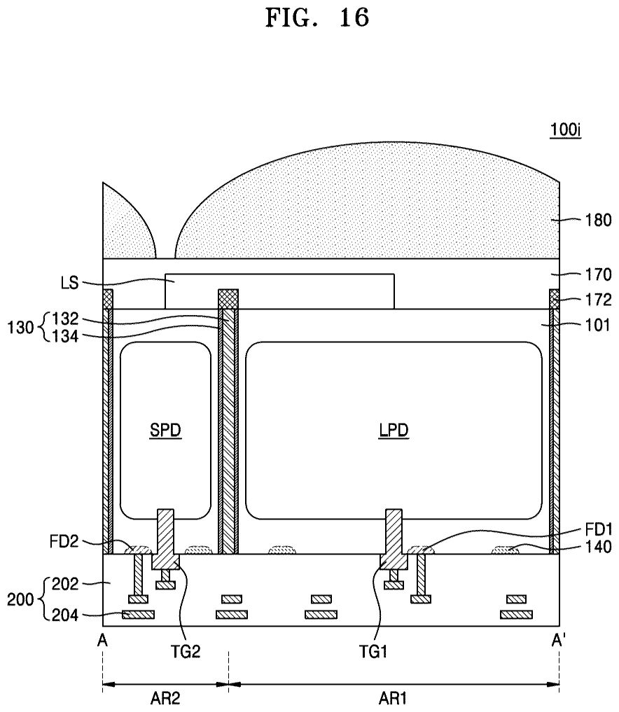

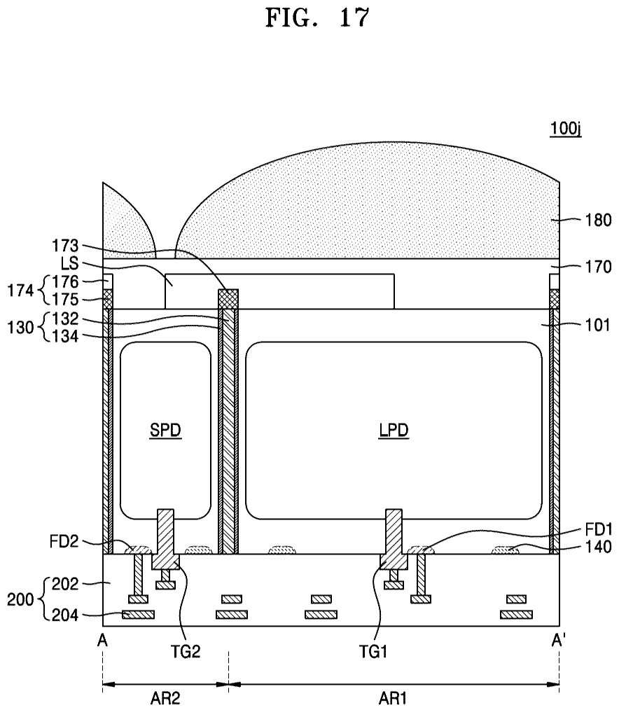

FIG. 16 is a diagram of an image sensor 100i according to some example embodiments and is a cross-sectional view of FIG. 5 taken along line A-A′. FIG. 17 is a diagram of an image sensor 100j according to some example embodiments and is a cross-sectional view of FIG. 5 taken along line A-A′. Hereinafter, the same descriptions as those given above with reference to FIGS. 5 and 6 are omitted, and only differences are described in detail.

Referring to FIG. 16, the light splitter LS of the image sensor 100i may be located between the substrate 101 and the color filter 170. The light splitter LS may directly cover the upper surface of the substrate 101. The light splitter LS may cover at least a portion of the metal grid 172 at the boundary between the first PD region AR1 and the second PD region AR2. The micro-lens 180 may be apart from the light splitter LS. The color filter 170 may cover the upper and side surfaces of the light splitter LS. In this case, for smooth traveling of light through the light splitter LS, at least a portion of the metal grid 172 at the boundary between the first PD region AR1 and the second PD region AR2 may be omitted.

Referring to FIG. 17, the image sensor 100j may include a first metal grid 173 and a second metal grid 174, instead of the metal grid 172 of the image sensor 100 in FIG. 6. The first metal grid 173 may correspond to a portion of the metal grid 172 in FIG. 6 disposed at the interface between the first PD region AR1 and the second PD region AR2. The second metal grid 174 may be the rest of the metal grid 172 in FIG. 6, except for the first metal grid 173. The first metal grid 173 may be a portion covered by the light splitter LS, and the second metal grid 174 may be a portion not covered by the light splitter LS. However, unlike the metal grid 172 in FIG. 6, the second metal grid may include a first portion 175 and a second portion 176. The first portion 175 and the second portion 176 may include materials having different refractive indices. The first metal grid 173 may include the same material as that of the first portion 175. The second portion 176 may include an insulator or a semiconductor material having a low refractive index, rather than metal.

The light splitter LS of the image sensor 100j may be located between the substrate 101 and the color filter 170, like the light splitter LS of the image sensor 100i in FIG. 16. The light splitter LS may directly cover the upper surface of the substrate 101. The light splitter LS may cover at least a portion of the first metal grid 173. The micro-lens 180 may be apart from the light splitter LS. The color filter 170 may cover the upper and side surfaces of the light splitter LS.

The light splitter LS may include the same material as the second portion 176. For this reason, when the first metal grid 173 and the second metal grid 174 are formed, the light splitter LS may also be formed together. That is, a manufacturing process of the image sensor 100j may be facilitated.

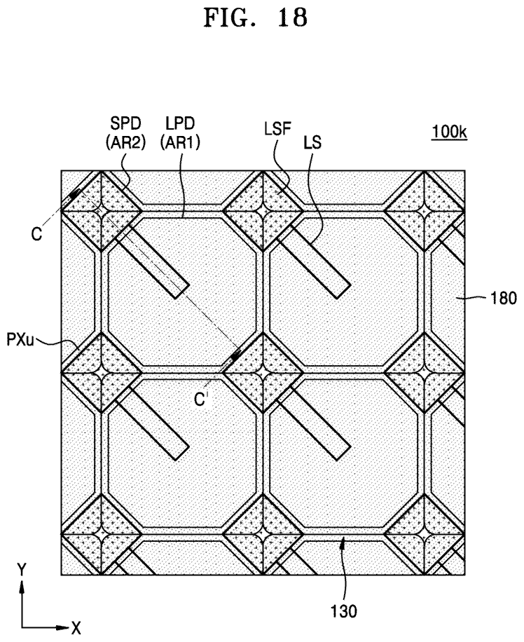

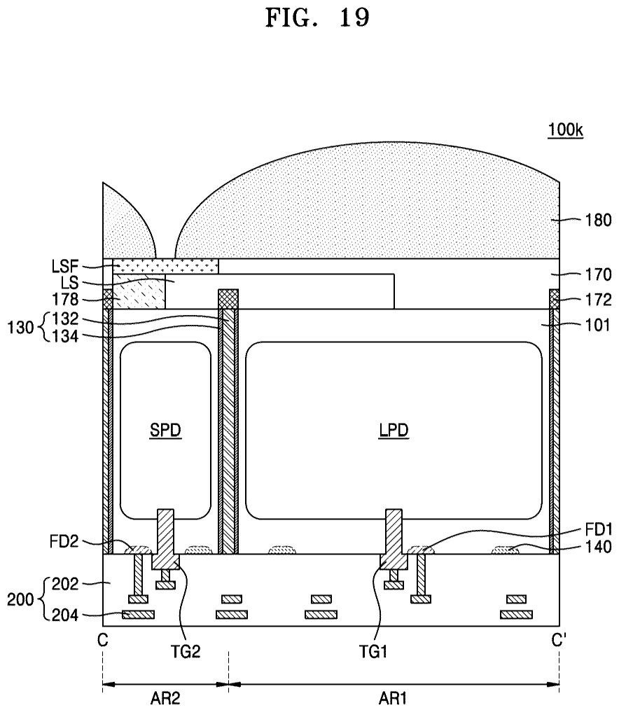

FIG. 18 is a plan view of an image sensor 100k according to some example embodiments. FIG. 19 is a diagram of the image sensor 100k according to some example embodiments and is a cross-sectional view of FIG. 18 taken along line C-C′. Hereinafter, the same descriptions as those given above with reference to FIGS. 5 and 6 are omitted, and only differences are described in detail.

Referring to FIGS. 18 and 19, the image sensor 100k may further include a filler 178 and a light blocking film LSF in the second PD region AR2. The filler 178 may be disposed on the upper surface of the substrate 101. The filler 178 may be disposed on the side of the light splitter LS. The filler 178 may be located between the light blocking film LSF and the substrate 101. The filler 178 may include an insulating material, such as silicon oxide, silicon nitride, and/or silicon oxynitride. Alternatively, the filler 178 may include the same material as that of the color filter 170.

The light blocking film LSF may be disposed on the light splitter LS and the filler 178. The light blocking film LSF may cover the second PD region AR2. A vertical level of an upper surface of the light blocking film LSF may be the same as, or lower or higher than, a vertical level of the upper surface of the color filter 170. The micro-lens 180 may cover a portion of the light blocking film LSF. The light blocking film LSF may include a metal, such as W, Al, and/or Cu.

Direct inflow of light into the second PD (SPD) may be limited or prevented due to the presence of the light blocking film LSF, and thus, the color filter 170 may be provided only in the first PD region AR1. Accordingly, the amount of light transferred to the second PD region AR2 may be more effectively adjusted, and thus, the sensitivity of the second PD (SPD) may be easily adjusted.

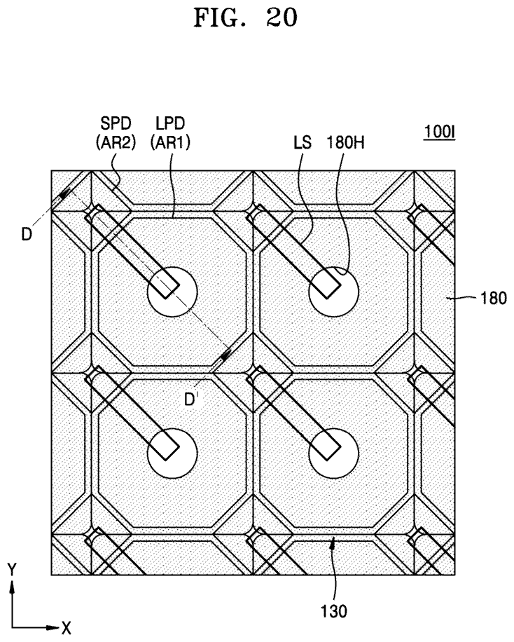

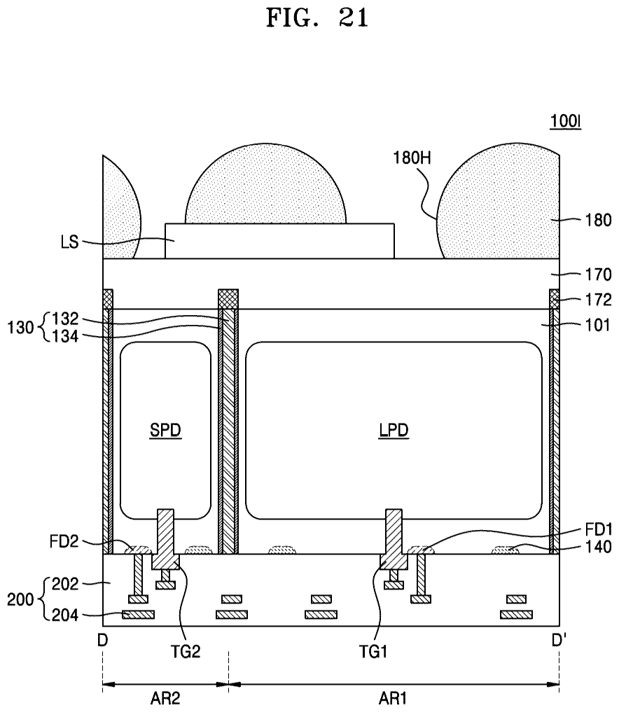

FIG. 20 is a plan view of an image sensor 1001 according to some example embodiments. FIG. 21 is a diagram of the image sensor 1001 according to some example embodiments and is a cross-sectional view of FIG. 20 taken along line D-D′. Hereinafter, the same descriptions as those given above with reference to FIGS. 5 and 6 are omitted, and only differences are described in detail.

Referring to FIGS. 20 and 21, the micro-lens 180 of the image sensor 1001 may include an opening 180H. In a plan view, the opening 180H may be formed at the center of the micro-lens 180 (or the center of the first PD region AR1). The micro-lens 180 may have a donut shape. In a plan view, the micro-lens 180 may have an annular shape. At least a portion of the light splitter LS may be exposed to the outside through the opening 180H in the first PD region AR1. In other words, at least a portion of the light splitter LS may vertically overlap the opening 180H in the first PD region AR1.

A cross-sectional shape of the micro-lens 180 excluding the opening 180H may be a portion of a circle. In some example embodiments, the cross-sectional shape of the micro-lens 180 may be semicircular.

As the opening 180H is formed at the center of the first PD region AR1, the amount of light incident to the light splitter LS in the first PD region AR1 may decrease. That is, by forming the opening 180H, the amount of light transferred to the second PD (SPD) may be adjusted.

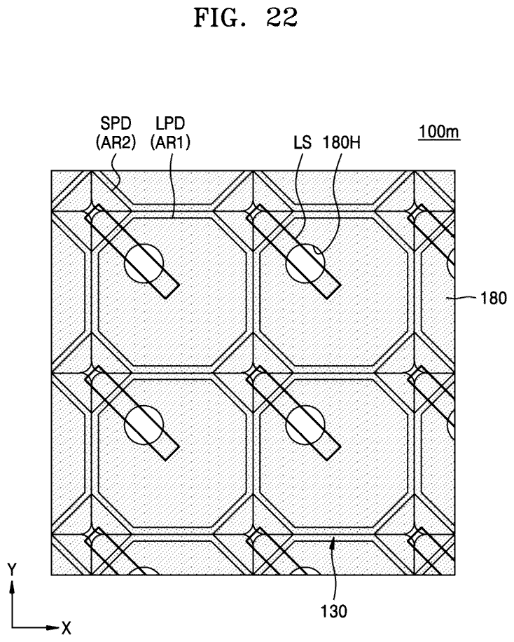

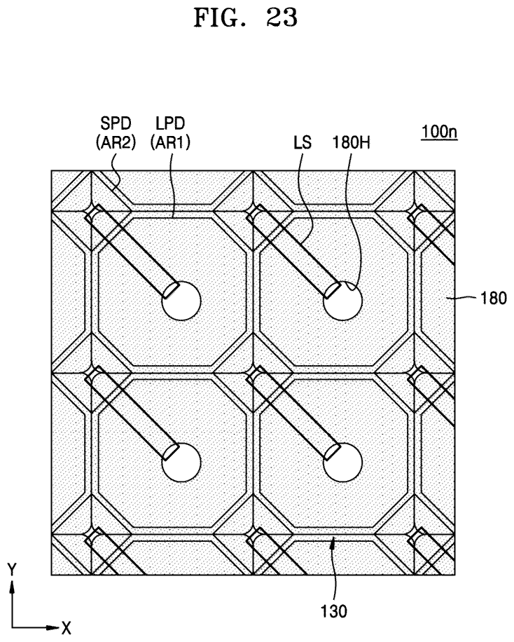

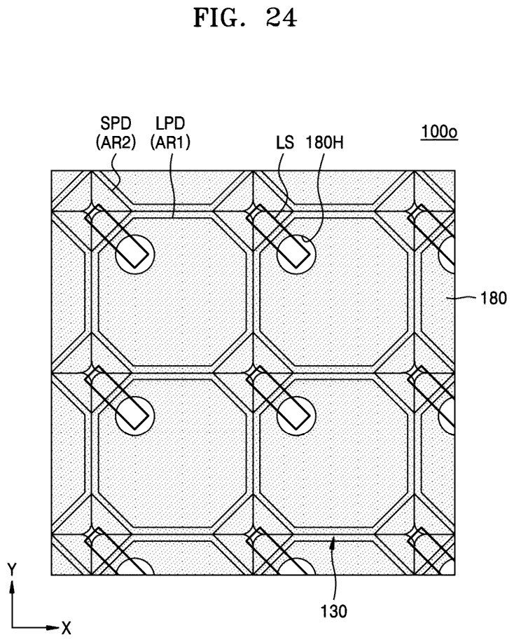

FIG. 22 is a plan view of an image sensor 100m according to some example embodiments. FIG. 23 is a plan view of an image sensor 100n according to some example embodiments. FIG. 24 is a plan view of an image sensor 1000 according to some example embodiments. Hereinafter, the same descriptions as those given above with reference to FIGS. 5 and 6 are omitted, and only differences are described in detail.

Referring to FIGS. 22, 23, and 24 and by comparison to FIG. 20, the position of the opening 180H formed in the micro-lenses 180 of the image sensors 100m, 100n, and 1000 may be variously changed. For example, as shown in FIG. 22, the opening 180H of the micro-lens 180 may be formed to be closer to the second PD region AR2 than to the center of the first PD region AR1. Alternatively, as shown in FIG. 23, the opening 180H of the micro-lens 180 may be formed to be away from the center of the first PD region AR1 in a direction away from the second PD region AR2. Accordingly, an area of the light splitter LS vertically overlapping the opening 180H may increase or decrease. Alternatively, as shown in FIG. 24, while reducing the length of the light splitter LS, a planar position of the opening 180H may also vertically overlap at least a portion of the light splitter LS. The amount of light transferred to the second PD (SPD) may be adjusted by determining the position of the opening 180H and adjusting the length of the light splitter LS as described above.

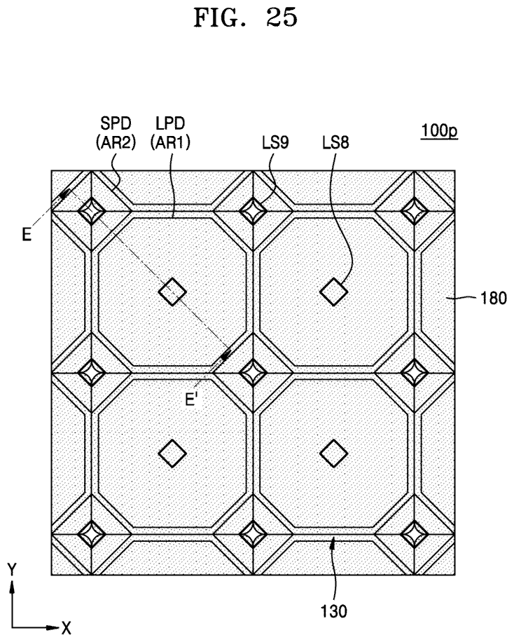

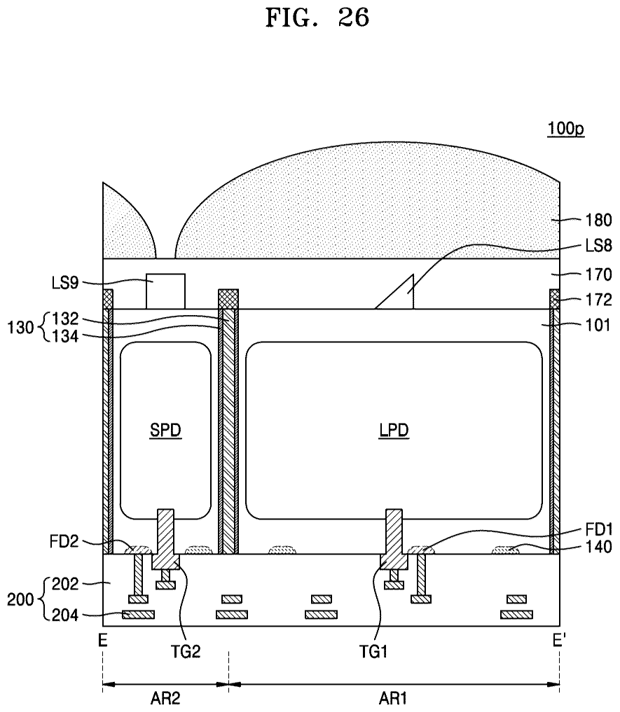

FIG. 25 is a plan view of an image sensor 100p according to some example embodiments. FIG. 26 is a view of the image sensor 100p according to some example embodiments and is a cross-sectional view of FIG. 25 taken along line E-E′. Hereinafter, the same descriptions as those given above with reference to FIGS. 5 and 6 are omitted, and only differences are described in detail.

Referring to FIGS. 25 and 26, the image sensor 100p may include a first splitter portion LS8 and a second splitter portion LS9, instead of the light splitter LS in FIGS. 5 and 6. The first splitter portion LS8 may be located between the substrate 101 and the color filter 170 in the first PD region AR1. The second splitter portion LS9 may be located between the substrate 101 and the color filter 170 in the second PD region AR2. The first splitter portion LS8 may have a triangular cross-sectional shape. The second splitter portion LS9 may have a shape, such as a cylindrical column, an elliptical column, a quadrangular column, or a polygonal column. The first splitter portion LS8 may function as a prism. That is, light incident on the first PD region AR1 may be transferred to the first splitter portion LS8, and light is reflected and refracted inside the first splitter portion LS8 and transferred to the second splitter portion LS9 in the second PD region AR2. The light transferred to the second splitter portion LS9 may be reflected and refracted to be transferred to the second PD (SPD). The first splitter portion LS8 and the second splitter portion LS9 may include the same material as that of the light splitter LS in FIGS. 5 and 6.

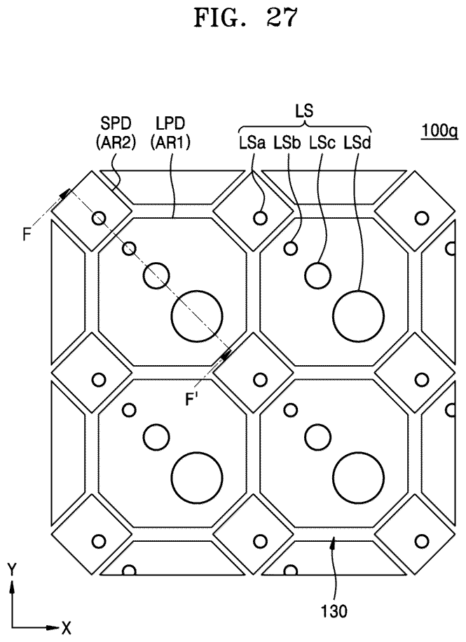

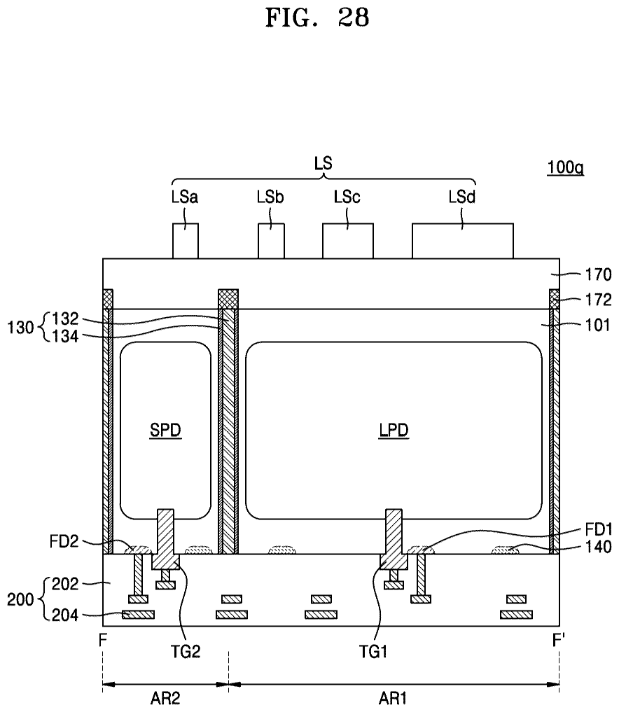

FIG. 27 is a plan view of an image sensor 100q according to some example embodiments. FIG. 28 is a view of the image sensor 100q according to some example embodiments and is a cross-sectional view of FIG. 27 taken along line F-F′. Hereinafter, the same descriptions as those given above with reference to FIGS. 5 and 6 are omitted, and only differences are described in detail.

Referring to FIGS. 27 and 28, the light splitter LS of the image sensor 100q may include mesa-shaped structures LSa, LSb, LSc, and LSd. Here, the image sensor 100q may not include the micro-lens 180. The mesa shape may refer to a shape having a flat upper surface and a side surface which is at a right angle or steep. For example, the mesa shape may include a cylinder. In FIG. 27, planar shapes of the structures LSa, LSb, LSc, and LSd are shown as circular, but are not limited thereto. Each of the structures LSa, LSb, LSc, and LSd may have various shapes, such as elliptical, triangular, quadrangular, and/or polygonal. Accordingly, the mesa shape may have various shapes, such as elliptical pillars, triangular pillars, quadrangular pillars, and/or polygonal pillars.

The structures LSa, LSb, LSc, and LSd may be apart from each other. Distances between the structures LSa, LSb, LSc, and LSd may be freely adjusted. A horizontal area of each of the structures LSa, LSb, LSc, and LSd may also be freely adjusted. By adjusting the distances between the structures LSa, LSb, LSc, and LSd and the horizontal area of each of the structures LSa, LSb, LSc, and LSd, light incident on the first PD region AR1 may be transferred onto the second PD region AR2 through reflection and refraction. That is, by adjusting the shapes and distances of the structures LSa, LSb, LSc, and LSd, the light splitter LS of the image sensor 100q may perform the same function (light distribution function) as that of the light splitter LS in FIGS. 5 and 6.

The structures LSa, LSb, LSc, and LSd of the light splitter LS of the image sensor 100q may include the same material as the material included in the light splitter LS of the image sensor 100 in FIGS. 5 and 6.

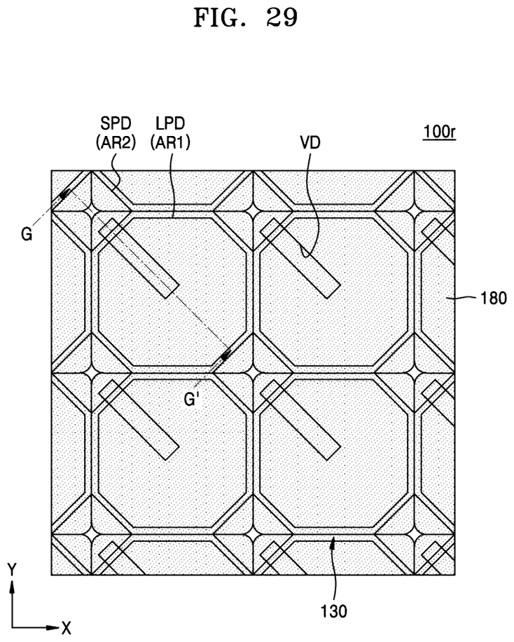

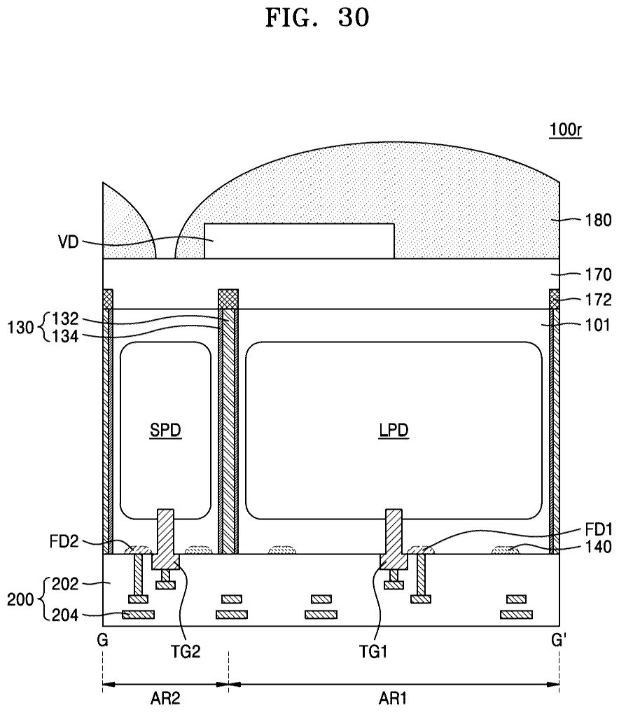

FIG. 29 is a plan view of an image sensor 100r according to some example embodiments. FIG. 30 is a view of the image sensor 100r according to some example embodiments and is a cross-sectional view of FIG. 29 taken along line G-G′. Hereinafter, the same descriptions as those given above with reference to FIGS. 5 and 6 are omitted, and only differences are described in detail.

Referring to FIGS. 29 and 30, the light splitter LS of FIGS. 5 and 6 may be omitted. Instead, a void VD may be formed inside the micro-lens 180 of the image sensor 100r. The void VD may be an empty space inside the micro-lens 180. For example, the void VD may include an air gap. Gas atoms or molecules may be included in the void VD. A refractive index of the void VD may be different from those of the micro-lens 180 and the color filter 170.

Light entering the micro-lens 180 may be incident into the void VD, and repeatedly reflected from an interface between the void VD and the micro-lens 180 and an interface between the void VD and the color filter 170, and may move from the first PD (LPD) onto the second PD (SPD). Light moving onto the second PD (SPD) may exit the void VD and be incident on the second PD (SPD). Accordingly, the void VD of the image sensor 100r may perform the same function as that of the light splitter LS in FIGS. 5 and 6. That is, the void VD of the image sensor 100r may perform a function of distributing light incident on the first PD region AR1 to the second PD region AR2.

The shape of the void VD may vary. In FIGS. 29 and 30, the planar and cross-sectional shapes of the voids VD are expressed as rectangular, but the inventive concepts are not limited thereto. The planar and/or cross-sectional shape of the void VD may be changed into various shapes, such as circular, elliptical, and polygonal. For example, the void VD may have a hemispherical shape. This may vary depending on the design of the image sensor 100r to be implemented.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While the inventive concepts have been particularly shown and described with reference to embodiments thereof, it will be understood that various changes in form and details may be made therein without departing from the spirit and scope of the following claims.

What is claimed is:

1. An image sensor comprising:
a substrate including a first photodiode (PD) region and a second PD region adjacent to the first PD region;
a first PD having a first area, the first PD in the first PD region;
a second PD having a second area smaller than the first area, the second PD in the second PD region;
a micro-lens on the substrate and covering the first PD region; and
a light splitter between the substrate and the micro-lens, and the light splitter including a material having a refractive index different from a refractive index of the micro-lens,
wherein the light splitter extends from the first PD region to the second PD region.

2. The image sensor of claim 1, wherein
the first PD region includes a center portion and an edge portion surrounding the center portion, and
a horizontal area of the light splitter in the second PD region is greater than a horizontal area of the light splitter in the edge portion of the first PD region.

3. The image sensor of claim 1, wherein
the first PD region includes a center portion and an edge portion surrounding the center portion, and
a horizontal area of the light splitter in the center portion of the first PD region is greater than a horizontal area of the light splitter in the edge portion of the first PD region.

4. The image sensor of claim 1, wherein the light splitter includes at least one of TiO₂, SiO₂, SiN, and amorphous silicon.

5. The image sensor of claim 1, wherein
a direction parallel to an upper surface of the substrate and from a center portion of the first PD region to a center portion of the second PD region is defined as a first direction,
a direction parallel to the upper surface of the substrate and perpendicular to the first direction is defined as a second direction, and
along the first direction from the center portion of the first PD to the center portion of the second PD, the light splitter has thickness in the second direction that varies.

6. The image sensor of claim 1, further comprising:
a deep trench isolation (DTI) that separates the first PD region from the second PD region, the light splitter vertically overlapping at least a portion of the DTI.

7. The image sensor of claim 6, further comprising:
a metal grid between the substrate and the micro-lens, the metal grid vertically overlapping at least a portion of the DTI, wherein in a plan vie, the metal grid is apart from the light splitter.

8. The image sensor of claim 6, further comprising:
a metal grid between the substrate and the micro-lens, and the metal grid vertically overlapping the DTI, wherein the light splitter covers at least a portion of the metal grid.

9. The image sensor of claim 1, further comprising:
a light blocking film covering the second PD region on the light splitter,
wherein the light blocking film includes metal.

10. The image sensor of claim 1, wherein
the micro-lens includes an opening exposing at least a portion of the light splitter in the first PD region, and
the micro-lens has an annular shape in a plan view.

11. An image sensor comprising:
a substrate in which a first photodiode (PD) region and a second PD region are defined;
a first PD having a first area in the substrate, the first PD in the first PD region;
a second PD in the substrate, in the second PD having a second area smaller than the first area, and the second PD in the second PD region;
a color filter on the substrate; and
a light splitter between the substrate and the color filter, or on the color filter,
wherein the light splitter includes a material having a refractive index different from a refractive index of the color filter, and
the light splitter vertically overlapping at least a portion of the first PD region and at least a portion of the second PD region.

12. The image sensor of claim 11, wherein the light splitter is on the color filter.

13. The image sensor of claim 12, further comprising:
a micro-lens on the light splitter,
wherein the micro-lens exposes at least a portion of the light splitter.

14. The image sensor of claim 12, wherein the light splitter includes mesa-shaped structures, and the mesa-shaped structures are apart from each other.

15. The image sensor of claim 11, wherein the light splitter is between the substrate and the color filter.

16. The image sensor of claim 15, wherein
the light splitter includes a first splitter portion vertically overlapping the first PD region and a second splitter portion vertically overlapping the second PD region,
the first splitter portion is apart from the second splitter portion, and
a cross-sectional shape of the first splitter portion is triangular.

17. The image sensor of claim 11, further comprising:
a micro-lens on the color filter,
wherein the micro-lens covers an entirety of the first PD region, and
the micro-lens vertically overlaps at least a portion of the second PD region.

18. The image sensor of claim 17, wherein the micro-lens exposes at least a portion of the color filter.

19. An image sensor comprising:
a substrate including a first photodiode (PD) region and a second PD region adjacent to the first PD region;
a first PD in the first PD region, and the first PD having a first area;
a second PD in the second PD region, and the second PD having a second area smaller than the first area;
a deep trench isolation (DTI) separating the first PD region from the second PD region and passing through the substrate;
a micro-lens on the substrate, and the micro-lens covering the first PD region;
a color filter between the substrate and the micro-lens;
a light splitter between the substrate and the color filter, or between the color filter and the micro-lens; and
an interconnection layer below the substrate, the interconnection layer including an insulating film and a conductive interconnection in the insulating film,
wherein the light splitter vertically overlaps at least a portion of the first PD region and at least a portion of the second PD region, and
the light splitter has a refractive index different from refractive indices of the micro-lens and the color filter.

20. The image sensor of claim 19, wherein
the image sensor includes a plurality of pixels arranged in a two-dimensional array structure,
the first PD region has an octagonal shape planarly, and the second PD region has a quadrangular shape planarly,
the first PD region is from among plural first PD regions, and the second PD region is from among plural second PD regions, and
four first PD regions from among the plural first PD regions surround one second PD region from among the plural second PD regions, and four second PD regions from among the plural second PD regions are alternately arranged on four sides among eight sides of one first PD region from among the plural first PD regions.
